(19) United States
(12) Patent Application Publication
(10) Pub. No.: US 2026/0040424 A1
(43) Pub. Date: Feb. 5, 2026

(54) TARGET GENERATION DEVICE, EXTREME ULTRAVIOLET LIGHT GENERATION SYSTEM, AND ELECTRONIC DEVICE MANUFACTURING METHOD

(71) Applicant: Gigaphoton Inc., Tochigi (JP)

(72) Inventor: Masaki NAKANO, Oyama-shi (JP)

(73) Assignee: Gigaphoton Inc., Tochigi (JP)

(21) Appl. No.: 19/231,120

(22) Filed: Jun. 6, 2025

(30) Foreign Application Priority Data
Jul. 30, 2024 (JP) 2024-123735

(51) Int. Cl. H05G 2/00; G03F 7/00

(52) U.S. Cl. CPC H05G 2/0023; H05G 2/0084; G03F 7/70033

(57) ABSTRACT

A target generation device includes nozzle including a nozzle hole through which a liquid target substance for generating extreme ultraviolet light is discharged; a first piezoelectric element arranged at a different position in a first direction with respect to the nozzle, and configured to vibrate the nozzle by expanding and contracting in the first direction; and a second piezoelectric element arranged at a different position in the first direction with respect to the first piezoelectric element, and configured to vibrate the nozzle via the first piezoelectric element by expanding and contracting in the first direction.

### CROSS-REFERENCE TO RELATED APPLICATIONS

The present application claims the benefit of Japanese Patent Application No. 2024-123735, filed on Jul. 30, 2024, the entire contents of which are hereby incorporated by reference.

### BACKGROUND

### 1. Technical Field

The present disclosure relates to a target generation device, an extreme ultraviolet light generation system, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: Japanese Patent Application Publication No. 2010-182555
Patent Document 2: US Patent Application Publication No. 2020/0166150
Patent Document 3: US Patent Application Publication No. 2012/0228526

### SUMMARY

A target generation device according to an aspect of the present disclosure includes a nozzle including a nozzle hole through which a liquid target substance for generating extreme ultraviolet light is discharged; a first piezoelectric element arranged at a different position in a first direction with respect to the nozzle, and configured to vibrate the nozzle by expanding and contracting in the first direction; and a second piezoelectric element arranged at a different position in the first direction with respect to the first piezoelectric element, and configured to vibrate nozzle via the first piezoelectric element by expanding and contracting in the first direction.

An electronic device manufacturing method according to an aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system includes a target generation device including a nozzle including a nozzle hole through which a liquid target substance for generating the extreme ultraviolet light is discharged, a first piezoelectric element arranged at a different position in a first direction with respect to the nozzle and configured to vibrate the nozzle by expanding and contracting in the first direction, and a second piezoelectric element arranged at a different position in the first direction with respect to the first piezoelectric element and configured to vibrate the nozzle via the first piezoelectric element by expanding and contracting in the first direction; a laser device configured to irradiate the target substance discharged from the nozzle with laser light; and an EUV light concentrating mirror configured to concentrate the extreme ultraviolet light generated by irradiating the target substance with the laser light.

An electronic device manufacturing method according to an aspect of the present disclosure includes inspecting a defect of a mask by irradiating the mask with extreme ultraviolet light generated by an extreme ultraviolet light generation system, selecting a mask using a result of the inspection, and exposing and transferring a pattern formed on the selected mask onto a photosensitive substrate. Here, the extreme ultraviolet light generation system includes a target generation device including a nozzle including a nozzle hole through which a liquid target substance for generating the extreme ultraviolet light is discharged, a first piezoelectric element arranged a different position in a first direction with respect to the nozzle and configured to vibrate the nozzle by expanding and contracting in the first direction, and a second piezoelectric element arranged at a different position in the first direction with respect to the first piezoelectric element and configured to vibrate the nozzle via the first piezoelectric element by expanding and contracting in the first direction; a laser device configured to irradiate the target substance discharged from the nozzle with laser light; and an EUV light concentrating mirror configured to concentrate the extreme ultraviolet light generated by irradiating the target substance with the laser light.

### BRIEF DESCRIPTION OF THE DRAWINGS

Embodiments of the present disclosure will be described below merely as examples with reference to the accompanying drawings.

FIG. 1 shows the configuration of an LPP EUV light generation system according to a comparative example.

FIG. 2 is a partial sectional view showing the configuration of a target generation device according to the comparative example.

FIG. 3 shows the configuration of a piezoelectric unit in the comparative example.

FIG. 4 shows the configuration of the piezoelectric unit in the comparative example.

FIG. 5 shows the configuration of the piezoelectric unit in the comparative example.

FIG. 6 is a flowchart showing operation of an EUV light generation processor including processing at abnormality of the piezoelectric unit in the comparative example.

FIG. 7 shows the configuration of the piezoelectric unit in a first embodiment.

FIG. 8 shows the configuration of the piezoelectric unit in the first embodiment.

FIG. 9 shows the configuration of the piezoelectric unit in the first embodiment.

FIG. 10 is a flowchart showing operation of the EUV light generation processor including processing at abnormality of the piezoelectric unit in the first embodiment.

FIG. 11 shows a switching circuit and a first operation example thereof in the first embodiment.

FIG. 12 shows the switching circuit and the first operation example thereof in the first embodiment.

FIG. 13 shows the switching circuit and the first operation example thereof in the first embodiment.

FIG. 14 shows the switching circuit and a second operation example thereof in the first embodiment.

FIG. 15 shows the switching circuit and the second operation example thereof in the first embodiment.

FIG. 16 shows the switching circuit and the second operation example thereof in the first embodiment.

FIG. 17 shows the configuration of the piezoelectric unit in a first modification.

FIG. 18 shows the configuration of the piezoelectric unit in the first modification.

FIG. 19 shows the configuration of the piezoelectric unit in the first modification.

FIG. 20 shows the configuration of the piezoelectric unit in a second modification.

FIG. 21 shows the configuration of the piezoelectric unit in the second modification.

FIG. 22 shows a first example of the switching circuit in the second modification.

FIG. 23 shows the first example of the switching circuit in the second modification.

FIG. 24 shows the first example of the switching circuit in the second modification.

FIG. 25 shows the first example of the switching circuit in the second modification.

FIG. 26 shows the first example of the switching circuit in the second modification.

FIG. 27 shows the first example of the switching circuit in the second modification.

FIG. 28 shows a second example of the switching circuit in the second modification.

FIG. 29 shows the second example of the switching circuit in the second modification.

FIG. 30 shows the second example of the switching circuit in the second modification.

FIG. 31 shows the second example of the switching circuit in the second modification.

FIG. 32 shows the second example of the switching circuit in the second modification.

FIG. 33 shows the second example of the switching circuit in the second modification.

FIG. 34 shows the configuration of the piezoelectric unit in a third modification.

FIG. 35 shows the configuration of the piezoelectric unit in the third modification.

FIG. 36 shows the configuration of the piezoelectric unit in a fourth modification.

FIG. 37 shows the configuration of the piezoelectric unit in the fourth modification.

FIG. 38 shows the configuration of the piezoelectric unit in a second embodiment.

FIG. 39 shows the configuration of the piezoelectric unit in the second embodiment.

FIG. 40 shows the configuration of the piezoelectric unit in a fifth modification.

FIG. 41 shows the configuration of the piezoelectric unit in the fifth modification.

FIG. 42 shows the configuration of the piezoelectric unit in a sixth modification.

FIG. 43 shows the configuration of the piezoelectric unit in the sixth modification.

FIG. 44 shows the configuration of the piezoelectric unit in a seventh modification.

FIG. 45 shows the configuration of the piezoelectric unit in the seventh modification.

FIG. 46 shows the configuration of an exposure apparatus connected to the EUV light generation system.

FIG. 47 shows the configuration of an inspection apparatus connected to the EUV light generation system.

### DESCRIPTION OF EMBODIMENTS

### <Contents>

1. Comparative example
1.1 EUV light generation system 11
   1.1.1 Configuration
   1.1.2 Operation
1.2. Target generation device 26
   1.2.1 Configuration
   1.2.2 Operation
1.3 Target sensor 4
   1.3.1 Configuration
   1.3.2 Operation
1.4 Piezoelectric unit 80
   1.4.1 Configuration
   1.4.2 Operation
1.5 Processing at abnormality of piezoelectric unit 80
   1.6 Problem of comparative example
      2. Piezoelectric unit 80a including plurality of piezoelectric elements arranged in X direction
2.1 Configuration
2.2 Processing at abnormality of piezoelectric unit 80a
2.3 Example of switching circuit 59
   2.3.1 First operation example
   2.3.2 Second operation example
2.4 First modification
2.5 Second modification
   2.5.1 Configuration
   2.5.2 First example of switching circuit 59
   2.5.3 Second example of switching circuit 59
2.6 Third modification
2.7 Fourth modification
2.8 Effect
   3. Piezoelectric unit 80a attached to bottom surface of nozzle 62
3.1 Fifth modification
3.2 Sixth modification
3.3 Seventh modification
3.4 Effect

### 4. Others

4.1 Examples of EUV light utilization apparatus 6
4.2 Processor
4.3 Supplement

Hereinafter, embodiments of the present disclosure will be described in detail with reference to the drawings. The embodiments described below shows some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. COMPARATIVE EXAMPLE

### 1.1 EUV Light Generation System 11

### 1.1.1 Configuration

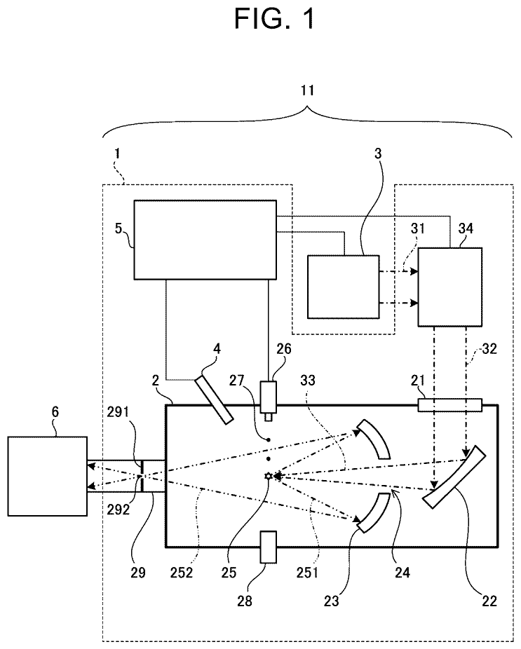

FIG. 1 shows the configuration of an LPP EUV light generation system 11 according to a comparative example. The comparative example of the present disclosure is an example recognized by the applicant as known only by the applicant, and is not a publicly known example admitted by the applicant. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a target generation device 26. The chamber 2 is a sealable container. The target generation device 26 supplies s a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 and laser light 32 output from the laser device 3 is transmitted through the window 21. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and laser light 33 passes through the through hole 24.

The EUV light generation apparatus 1 includes an EUV light generation processor 5, a target sensor 4, and the like. The configuration of the EUV light generation processor 5 will be described later. The target sensor 4 detects at least one of the presence, trajectory, position, and velocity of the target 27. The target sensor 4 may have an imaging function.

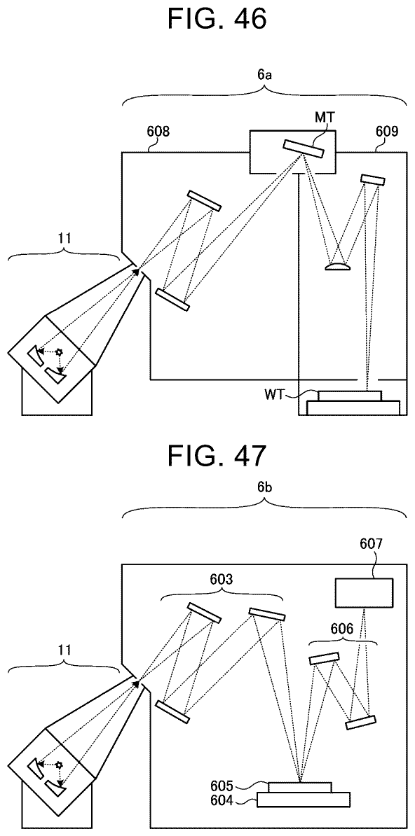

Further, the EUV light generation apparatus 1 includes a connection portion 29 providing communication between the internal space of the chamber 2 and the internal space of an EUV light utilization apparatus 6. The EUV light utilization apparatus 6 may be an exposure apparatus 6a shown in FIG. 46 or an inspection apparatus 6b shown in FIG. 47. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of the laser light 32, and an actuator for adjusting the position, posture, and the like of the optical element.

### 1.1.2 Operation

Operation of the EUV light generation system 11 will be described with reference to FIG. 1. Pulse laser light 31 output from the laser device 3 enters, via the laser light transmission device 34, the chamber 2 through the window 21 as the laser light 32. The laser light 32 travels along a laser light path in the chamber 2, is reflected by the laser light concentrating mirror 22, and is radiated to the target 27 as the laser light 33.

The target generation device 26 outputs the target 27 toward the plasma generation region 25 in the chamber 2. The target 27 is irradiated with the laser light 33. The target 27 irradiated with the laser light 33 is turned into plasma, and radiation light 251 is radiated from the plasma. EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. One target 27 may be irradiated with a plurality of pulses included in the laser light 33.

The EUV light generation processor 5 controls the entire EUV light generation system 11. The EUV light generation processor 5 processes a detection result of the target sensor 4. Based on the detection result of the target sensor 4, the EUV light generation processor 5 controls the timing at which the target 27 is output, the output direction of the target 27, and the like. Further, the EUV light generation processor 5 controls oscillation timing of the laser device 3, the travel direction of the laser light 32, the concentration position of the laser light 33, and the like. The above-described various kinds of control are merely examples, and other control may be added as necessary.

### 1.2. Target Generation Device 26

### 1.2.1 Configuration

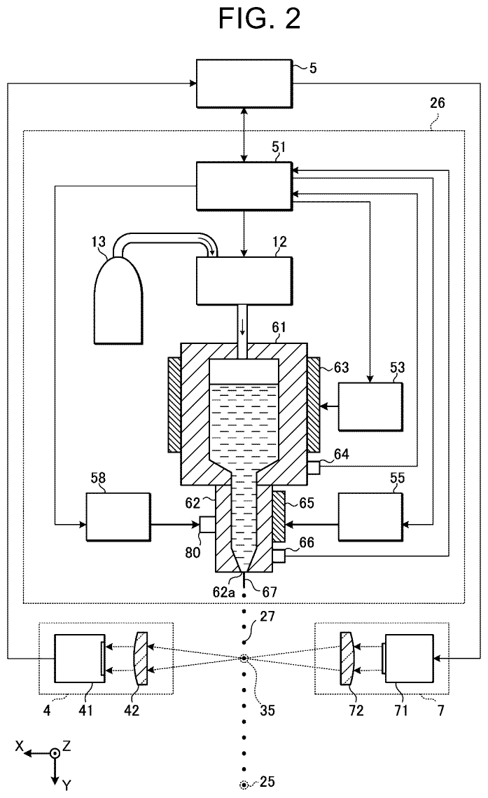

FIG. 2 is a partial sectional view showing the configuration of the EUV light generation apparatus 26 according to the comparative example. The target generation device 26 includes a pressure regulator 12, an inert gas cylinder 13, a target generation processor 51, heater power sources 53, 55, a piezoelectric element power source 58, a reservoir tank 61, and a nozzle 62. The nozzle 62 includes nozzle hole 62a. The configuration of the target generation processor 51 will be described later.

The output direction of the target 27 is defined as a Y direction. A line passing through the center of the nozzle hole 62a in the Y direction is defined as a center axis of the nozzle 62, and the direction perpendicularly directing from the center axis toward the piezoelectric unit 80 is defined as an X direction. The direction perpendicular to both the X direction and the Y direction is defined as a Z direction.

The reservoir tank 61 stores a target substance containing, for example, tin in a molten state. A heater 63 is attached to the reservoir tank 61 to melt the target substance and to maintain the molten state. The heater power source 53 is connected to the heater 63. A temperature sensor 64 is further attached to the reservoir tank 61.

The nozzle 62 is connected to a lower end of the reservoir tank 61, and the nozzle hole 62a is located at a lowermost end of the nozzle 62. The liquid target substance stored in the reservoir tank 61 passes through the inside of the nozzle 62 toward the nozzle hole 62a. In order to maintain the molten state of the target substance inside the nozzle 62, a heater 65 is also attached to the nozzle 62. The heater power source 55 is connected to the heater 65. A temperature sensor 66 is further attached to the nozzle 62.

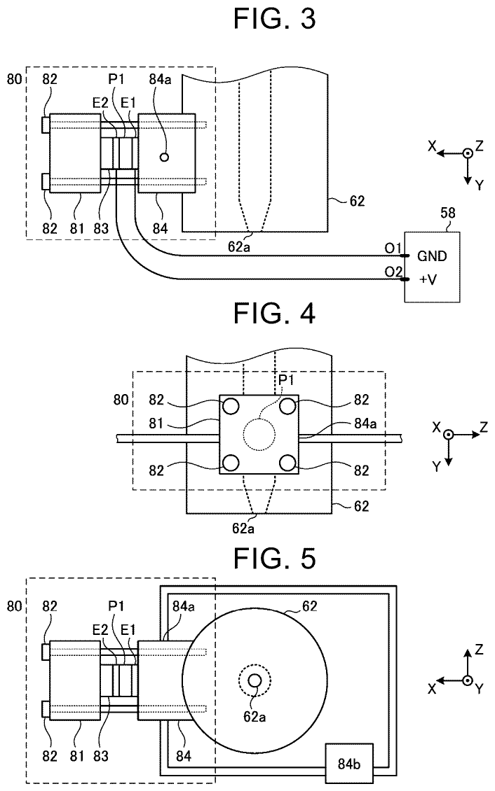

The piezoelectric unit 80 is further attached to the nozzle 62. The piezoelectric unit 80: may include a piezoelectric crystal such as lead zirconate titanate (PZT) and an electrode attached to the piezoelectric crystal. The piezoelectric crystal and the electrode will be described later with reference to FIGS. 3 and 5. The piezoelectric element power source 58 is connected to the piezoelectric unit 80. When the piezoelectric element power source 58 applies a drive voltage to the piezoelectric crystal included in the piezoelectric unit 80, the nozzle 62 is vibrated.

The inert gas cylinder 13 is connected to the pressure regulator 12 by a gas pipe. The pressure regulator 12 is in communication with the inside of the reservoir tank 61 by another gas pipe. An inert gas is supplied from the inert gas cylinder 13 to the inside of the reservoir tank 61 via these gas pipes.

### 1.2.2 Operation

The target generation processor 51 controls the value of the current flowing from the heater power source 53 to the heater 63 so that the detection value detected by the temperature sensor 64 is maintained at a target temperature. The target generation processor 51 controls the value of the current flowing from the heater power source 55 to the heater 65 so that the detection value detected by the temperature sensor 66 is maintained at a target temperature.

The pressure regulator 12 adjusts the pressure of the inert gas supplied from the inert gas cylinder 13 into the reservoir tank 61 in response to a control signal output from the target generation processor 51. The inert gas introduced into the reservoir tank 61 pressurizes the molten target substance in the reservoir tank 61. When the inert gas pressurizes the target substance, a jet 67 of the liquid target substance is discharged from the nozzle hole 62a of the nozzle 62.

The piezoelectric element power source 58 applies the drive voltage having a waveform corresponding to a control signal output from the target generation processor 51 to the piezoelectric crystal included in the piezoelectric unit 80. As a result, the piezoelectric crystal periodically expands and contracts, and applies vibration to the nozzle 62. When the vibration applied to the nozzle 62 satisfies a predetermined condition, a standing wave is generated in the jet 67 of the target substance discharged from the nozzle hole 62a. Due to the surface tension of the target substance, the jet 67 is separated into droplets, and a plurality of targets 27 are generated.

The target 27 output into the chamber 2 is supplied to the plasma generation region 25 in the chamber 2. The EUV light generation processor 5 controls the laser device 3 so that the target 27 output from the target generation device 26 is irradiated with the laser light 33.

### 1.3. Target Sensor 4

### 1.3.1 Configuration

The target sensor 4 is used with a light emission unit 7. The target sensor 4 and the light emission unit 7 are arranged on opposite sides of a trajectory of the target 27 discharged along the center axis of the nozzle 62. The target sensor 4 includes an optical sensor 41 and a light receiving optical system 42. The light emission unit 7 includes a light source 71 and an illumination optical system 72.

### 1.3.2 Operation

The light source 71 emits light continuously in accordance with a control signal output from the EUV light generation processor 5. The illumination optical system 72 concentrates the light output from the light source 71 into a region 35 including a predetermined position of the trajectory of the target 27 and a position in the vicinity thereof. The light receiving optical system 42 guides the light output from the light emission unit 7 to the light receiving surface of the optical sensor 41.

When the target 27 passes through the region 35 illuminated by the light emission unit 7, a part of the light output from the light emission unit 7 is blocked by the target 27 before the light reaches the target sensor 4. As a result, the light amount of light incident on the optical sensor 41 can be reduced. The optical sensor 41 detects a change in the light amount of incident light, and outputs target detection signal to the EUV light generation processor 5.

### 1.4 Piezoelectric Unit 80

### 1.4.1 Configuration

FIGS. 3 to 5 show the configuration of the piezoelectric unit 80 in the comparative example. FIGS. 3, 4, and 5 show a state of the piezoelectric unit 80 as viewing in the −Z direction, the −X direction, and the −Y direction, respectively.

In the piezoelectric unit 80 attached to the side surface of the nozzle 62, a cooling member 84, a piezoelectric element, an insulating member 83, and a pressing member 81 are arranged in this order in the X direction from the side closer to the nozzle 62. The piezoelectric element includes a piezoelectric crystal P1 and electrodes E1, E2. Each of a plurality of bolts 82 penetrates the pressing member 81 and the cooling member 84 and is fixed to the nozzle 62. The electrodes E1, E2, the pressing member 81, the bolts 82, and the cooling member 84 are made of a metal. There is a gap between the electrode E2 and the bolts 82 so as not to be electrically connected. The X direction is an example of the first direction in the present disclosure.

The electrodes E1, E2 are connected to first and second output terminals O1, O2 of the piezoelectric element power source 58, respectively. The piezoelectric element power source 58 generates a voltage between the first and second output terminals O1, O2. The potential of the first output terminal O1 is, for example, a ground potential GND, and the potential of the second output terminal O2 is, for example, a potential +V that varies in a pulse manner.

The cooling member 84 includes a flow path 84a of a cooling medium, and the flow path 84a is connected to a chiller 84b by a pipe. The chiller 84b includes a pump (not shown) and a heat exchanger (not shown).

### 1.4.2 Operation

The piezoelectric crystal P1 expands and contracts in the X direction in accordance with an electric field generated in the piezoelectric crystal P1 by the voltage applied between the electrodes E1, E2. Since the piezoelectric crystal P1 is pressed in the −X direction by the pressing member 81, the nozzle 62 is vibrated by the expansion and contraction of the piezoelectric crystal P1.

The nozzle 62 is connected to the ground potential GND similarly to the electrode E1. The nozzle 62 and the electrode E1 may not be insulated from each other. The pressing member 81 is also connected to the ground potential GND via the bolts 82 and the nozzle 62. The insulating member 83 ensures insulation between the pressing member 81 and the electrode E2.

The nozzle 62 has a temperature equal to or higher than the melting point of tin, and the temperature thereof may exceed an upper limit of a use temperature range of the piezoelectric crystal P1, but by providing the cooling member 84 between the nozzle 62 and the piezoelectric crystal P1, the temperature of the piezoelectric crystal P1 is suppressed to be equal to or lower than the upper limit of the use temperature range. A temperature sensor (not shown) may be provided at the cooling member 84, and the target generation processor 51 may control the chiller 84b in accordance with the detection result of the temperature sensor.

### 1.5 Processing at Abnormality of Piezoelectric Unit 80

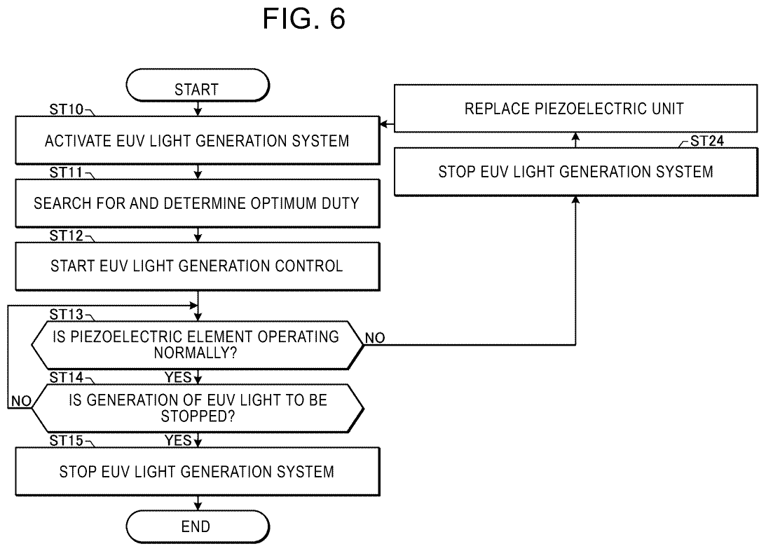

FIG. 6 is a flowchart showing operation of the EUV light generation processor 5 including processing at abnormality of the piezoelectric unit 80 in the comparative example.

In ST10, the EUV light generation processor 5 performs activation operation of the EUV light generation system 11. The activation operation of the EUV light generation system 11 includes following processes A to C.

### Process A: Buffer Gas Supply to Chamber 2

The EUV light generation processor 5 controls an exhaust pump (not shown), a buffer gas supply device (not shown), a gas pressure sensor (not shown), and the like to set the chamber 2 in a vacuum state, and then supplies the buffer gas to the chamber. 2 to be maintained at a predetermined pressure.

### Process B: Activation of Target Generation Device 26

The EUV light generation processor 5 transmits a command signal for activating the target generation device 26 to the target generation processor 51. The target generation processor 51 controls the heater power sources 53, 55 to heat and melt the target substance in the reservoir tank 61 and the nozzle 62 and maintain the target substance at a predetermined temperature. The target generation processor 51 controls the pressure regulator 12 so that the pressure inside the reservoir tank 61 is adjusted, and controls the piezoelectric element power source 58 so that the piezoelectric unit 80 vibrates the nozzle 62.

### Process C: Others

The EUV light generation processor 5 activates the target sensor 4 and the light emission unit 7, and starts detecting the target 27. The detection result of the target 27 is transmitted from the EUV light generation processor 5 to the target generation processor 51. The EUV light generation processor 5 performs activation operation for generating the EUV light including activation of a plasma generation region imaging device (not shown), activation of the laser device 3 and the laser light transmission device 34, and the like.

In ST11, the EUV light generation processor 5 transmits, to the target generation processor 51, a command signal for searching for and determining an optimum duty. The searching for the optimum duty means to acquire the detection result of the target 27 discharged from the nozzle 62 while changing a duty ratio, which is a ratio of the on-time in the waveform of the voltage applied to the piezoelectric element, and to search for an appropriate value of the duty ratio. The duty ratio is changed, for example, from 1% to 99% in increments of 0.1%. As the detection result of the target 27, for example, it is determined whether or not the diameter of the target 27 and the interval between two targets 27 are each within a range of normal values. The target generation processor 51 determines, as the optimum duty, a center value of the widest range among ranges each having continuous values of the duty ratio with which an abnormal value occurrence rate in the detection result of the target 27 is less than a threshold.

There may be a case in which the optimum duty is not found only through the duty ratio searching. In such a case, the temperature of the nozzle 62 measured by the temperature sensor 66 may be changed to search for the duty ratio again. When the optimum duty is not found even if the temperature of the nozzle 62 is changed a plurality of times, the voltage at the on-time in the waveform of the voltage to be applied to the piezoelectric element may be changed to search for the duty ratio again.

In ST12, the EUV light generation processor 5 starts generation control of the EUV light so that the EUV light generation system 11 starts generation of the EUV light. The target generation processor 51 monitors the abnormal value occurrence rate of the detection result of the target 27, and controls the duty ratio on the basis of the optimum duty so that the abnormal value occurrence rate is optimized.

In ST13, the EUV light generation processor 5 transmits a command signal for determining operation of the piezoelectric element to the target generation processor 51. The target generation processor 51 determines whether or not the piezoelectric element is operating normally based on the detection result of the target 27 by the target sensor 4. For example, when the abnormal value occurrence rate is equal to or less than the threshold, it is determined that the piezoelectric element is operating normally, and when the abnormal value occurrence rate still exceeds the threshold even after the duty ratio is controlled so that the abnormal value occurrence rate is optimized, it is determined that the piezoelectric element is not operating normally. When the piezoelectric element is operating normally (ST13:YES), the EUV light generation processor 5 advances processing to ST14. When the piezoelectric element is not operating normally (ST13:NO), the EUV light generation processor 5 advances processing to ST24.

In ST14, the EUV light generation processor 5 determines whether or not to stop the generation of the EUV light. When the generation of the EUV light is to be stopped (ST14:YES), the EUV light generation processor 5 advances processing to ST15. When the generation of the EUV light is not to be stopped (ST14:NO), the EUV light generation processor 5 returns processing to ST13.

In ST15, the EUV light generation processor 5 performs a process for stopping the EUV light generation system 11 activated in ST10. After ST15, the EUV light generation processor 5 ends processing of the present flowchart.

Also in ST24, the EUV light generation processor 5 performs a process for stopping the EUV light generation system 11. After ST24, an operator of the EUV generation system 11 performs replacement of the piezoelectric unit 80. The replacement of the piezoelectric unit 80 may involve replacement of the target generation device 26. After the replacement of the piezoelectric unit 80, the EUV light generation processor 5 returns processing to ST10.

### 1.6 Problem of Comparative Example

As described with reference to FIG. 6, when the piezoelectric element included in the piezoelectric unit 80 is not operating normally, the piezoelectric unit 80 needs to be replaced. Since the nozzle 62 to which the piezoelectric unit 80 is attached is in the chamber 2, at least the chamber 2 needs to be opened to replace the piezoelectric unit 80, and after the replacement of the piezoelectric unit 80, it is required to reactivate the EUV light generation system 11 as returning to ST10. Therefore, downtime in which the EUV light cannot be generated occurs. Further, since the reservoir tank 61 and the nozzle 62 are hot immediately after the EUV light generation system 11 is stopped, it may not be realistic to perform the replacement operation as removing only the piezoelectric unit 80 from the nozzle 62. In this case, even if abnormality occurs only at the piezoelectric element, the cost of replacing the entire target generation device 26 is incurred.

It is also conceivable to mount a spare piezoelectric unit on the nozzle 62 in addition to the piezoelectric unit 80. However, since the occupied volume of the piezoelectric unit is large, the number of mounted piezoelectric units that can be installed on the nozzle 62 is at most two.

Further, even if switching to the spare piezoelectric unit is performed, the searching for the optimum duty in ST11 needs to be performed again, and downtime also occurs.

### 2. PIEZOELECTRIC UNIT 80A INCLUDING PLURALITY OF PIEZOELECTRIC ELEMENTS ARRANGED IN X DIRECTION

### 2.1 Configuration

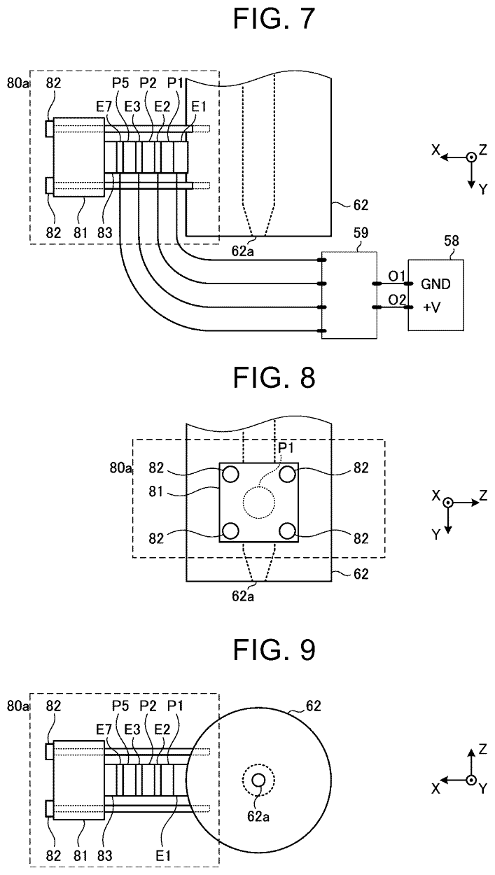

FIGS. 7 to 9 show the configuration of a piezoelectric unit 80a in a first embodiment. In the piezoelectric unit 80a attached to the side surface of the nozzle 62, first, second, and fifth piezoelectric elements, the insulating member 83, and the pressing member 81 are arranged in this order in the X direction from the side closer to the nozzle 62. Third and fourth piezoelectric elements will be described in a second modification.

The first piezoelectric element includes the electrode E1, the piezoelectric crystal P1, and the electrode E2. The second piezoelectric element includes the electrode E2, a piezoelectric crystal P2, and an electrode E3. The fifth piezoelectric element includes the electrode E3, a piezoelectric crystal P5, and an electrode E7. In this way, the first piezoelectric element is arranged at a position in the X direction with respect to the nozzle 62, the second piezoelectric element is arranged at a position in the X direction with respect to the first piezoelectric element, the fifth piezoelectric element is arranged at a position in the X direction with respect to the second piezoelectric element, and the pressing member 81 is arranged at a position in the X direction with respect to the fifth piezoelectric element. Here, the first and second piezoelectric elements share the electrode E2, and the second and fifth piezoelectric elements share the electrode E3. The insulating member 83 is arranged between the pressing member 81 and the electrode E7. Each of the plurality of bolts 82 penetrates the pressing member 81 and is fixed to the nozzle 62. The electrodes E1, E2, E3 correspond to the first, second, and third electrodes in the present disclosure, respectively.

The electrodes E1 to E3 and E7 are connected to a switching circuit 59 by electric wires, respectively. The switching circuit 59 is connected to first and second output terminals O1, O2 of the piezoelectric element power source 58. The switching circuit 59 switches connection between the first and second output terminals O1, O2 and the electrodes E1 to E3 and E7 into any of the following states a to c.
State a: A state in which the first output terminal O1 is connected to the electrode E1 and the second output terminal O2 is connected to the electrode E2
State b: A state in which the first output terminal O1 is connected to the electrode E2 and the second output terminal O2 is connected to the electrode E3
State c: A state in which the first output terminal O1 is connected to the electrode E3 and the second output terminal O2 is connected to the electrode E7

The state a corresponds to the first state in the present disclosure, and the state b corresponds to the second state in the present disclosure. The piezoelectric element power source 58 applies a voltage to the first piezoelectric element in the state a, applies a voltage to the second piezoelectric element in the state b, and applies a voltage to the fifth piezoelectric element in the state c. Main vibration directions of the first, second, and fifth piezoelectric elements are the same, and when a voltage is applied to each of them, the nozzle 62 is vibrated by the expansion and contraction thereof in the X direction.

Here, description has been provided on a case in which three piezoelectric elements are included in the piezoelectric unit 80a. However, two or four or more piezoelectric elements may be included. Further, the piezoelectric crystal P1 may be in direct contact with the nozzle 62 so that a conductive member of the nozzle 62 also serves as the electrode E1.

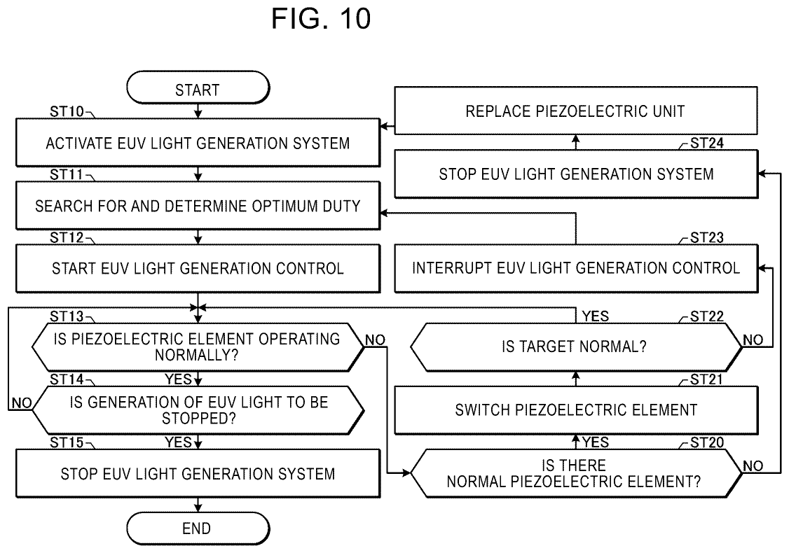

2.2 Processing at Abnormality of Piezoelectric Unit 80a FIG. 10 is a flowchart showing operation of the EUV light generation processor 5 including processing at abnormality of the piezoelectric unit 80a in the first embodiment.

Processes in ST10 to ST15 are similar to those of the comparative example. In the first embodiment, when the piezoelectric device is not operating normally (ST13:NO), the EUV light generation processor 5 advances processing to ST20.

In ST20, the EUV light generation processor 5 determines whether or not there is a normal piezoelectric element in the piezoelectric unit 80a. The EUV light generation processor 5 may store a normal or abnormal state of each piezoelectric element in a memory (not shown), and determine the normal or abnormal state based on the stored data in the memory. When there is a normal piezoelectric element (ST20:YES), the EUV light generation processor advances processing to ST21. When there is no normal piezoelectric element (ST20:NO), the EUV light generation processor 5 advances processing to ST24. The processes in ST24 and thereafter are similar to those in the comparative example.

In ST21, the EUV light generation processor 5 transmits a switching signal of the piezoelectric element to the target generation processor 51, and the target generation processor 51 performs switching of the piezoelectric element. The switching of the piezoelectric element is performed by, for example, switching from the state a to the state b or switching from the state b to the state c.

In ST22, the EUV light generation processor 5 transmits a command signal for determining whether the target 27 is normal to the target generation processor 51. The target generation processor 51 determines whether or not the target 27 is normally generated based on the detection result of the target 27 by the target sensor 4. For example, when the abnormal value occurrence rate is equal to or less than the threshold, it is determined that the target 27 is normally generated, and when the abnormal the threshold, is value occurrence rate exceeds it determined that the target 27 is not normally generated. When the target 27 is normally generated (ST22:YES), the EUV light generation processor 5 returns processing to ST13 and continues processing of generating the EUV light by the EUV light generation system 11. When the target 27 is not normally generated (ST22:NO), the EUV light generation processor 5 advances processing to ST23.

In ST23, the EUV light generation processor 5 interrupts the generation control of the EUV light started in ST12, returns and processing to ST11. When the determination result in ST22 is NO due to the switching of the piezoelectric elements, re-searching for the optimum duty (ST11) is required, but stopping (ST24) and reactivating (ST10) of the EUV light generation system 11 can be avoided. Further, when the determination result in ST22 is YES, it is possible to avoid re-searching for the optimum duty as well.

### 2.3 Example of Switching Circuit 59

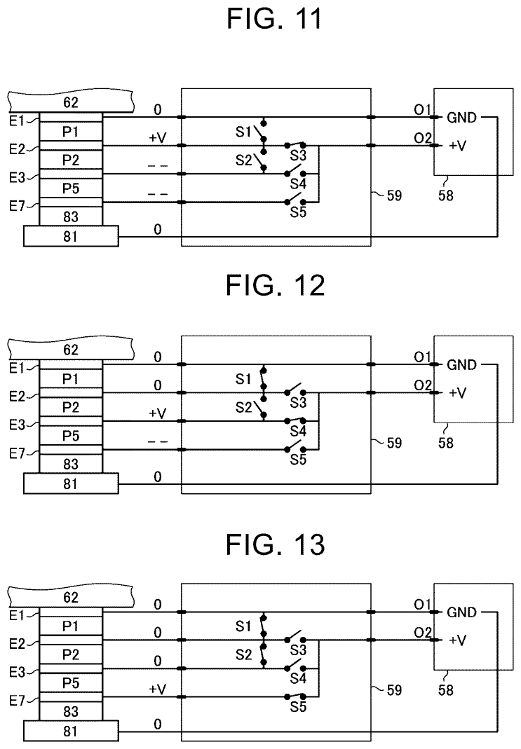

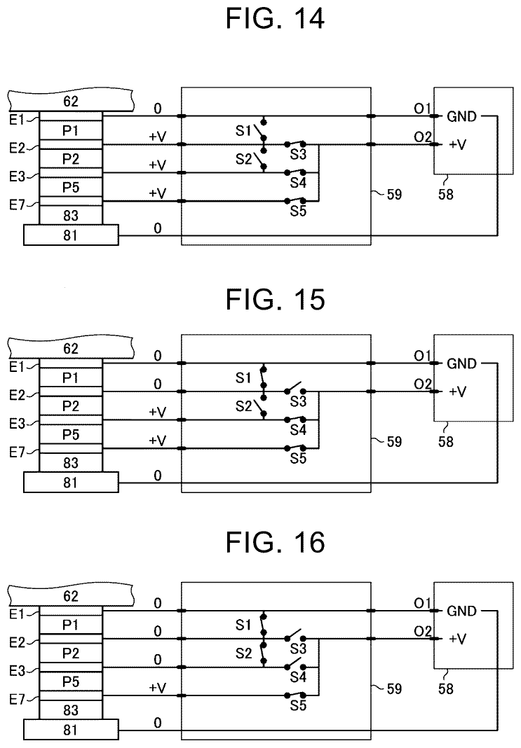

FIGS. 11 to 16 show an example of the switching circuit 59 in the first embodiment. FIGS. 11 to 16 all show the same circuit, while FIGS. 11 to 13 show a first operation example, and FIGS. 14 to 16 show a second operation example.

The switching circuit 59 includes two input terminals connected to the first and second output terminals O1, O2, respectively, and four output terminals connected to the electrodes E1 to E3 and E7, respectively. The first output terminal O1 is short-circuited to the electrode E1. The electrode E1 and the electrode E2 are connected via a switch S1. The electrode E2 and the electrode E3 are connected via a switch S2. The second output terminal O2 is connected to the electrodes E2, E3, E7 via switches S3, S4, S5, respectively.

### 2.3.1 First Operation Example

When the switch S3 is turned on and the switches S1, S2, S4, S5 are turned off as shown in FIG. 11, the first output terminal O1 is connected to the electrode E1 and the second output terminal O2 is connected to the electrode E2 to be in the state a.

When the switches S1, S4 are turned on and the switches S2, S3, S5 are turned off as shown in FIG. 12, the first output terminal O1 is connected to the electrode E2 and the second output terminal O2 is connected to the electrode E3 to be in the state b.

When the switches S1, S2, S5 are turned on and the switches S3, S4 are turned off as shown in FIG. 13, the first output terminal O1 is connected to the electrode E3 and the second output terminal O2 is connected to the electrode E7 to be in the state c.

With the operation described above, one of the first, second, and fifth piezoelectric elements can be used, and when it fails to operate normally, another one thereof can be used.

Since the first, second, and fifth piezoelectric elements do not necessarily have exactly the same characteristics, in ST22 of FIG. 10, the target 27 may not be generated normally and re-searching for the optimum duty may be required. However, since the pressing force of the pressing member 81 by tightening the bolts 82, or the mounting position of the piezoelectric unit 80a, for example, is common to the first, second, and fifth piezoelectric elements, it is highly likely that re-searching for the optimum duty is unnecessary rather than switching to another piezoelectric unit. As a result, downtime can be suppressed.

As described above, the pressing member 81 is connected to the ground potential GND via the bolts 82 and the nozzle 62. On the other hand, in FIG. 11, the electrode E2 is connected to the potential +V. Due to the potential difference of +V generated between the electrode E2 and the pressing member 81, an electric field may be generated inside the piezoelectric crystals P2, P5 in a direction opposite to the electric field inside the piezoelectric crystal P1, and the piezoelectric crystals P2, P5 may expand and contract in accordance with the electric field. By increasing the thickness of the insulating member 83, the electric field inside the piezoelectric crystals P2, P5 can be reduced to reduce the expansion and contraction of the piezoelectric crystals P2, P5, but cannot be reduced to zero. Therefore, the expansion and contraction of the piezoelectric crystals P2, P5 may weaken the vibration toward the nozzle 62 caused by the expansion and contraction of the piezoelectric crystal P1. In FIG. 12 as well, due to a potential difference of +V generated between the electrode E3 and the pressing member 81, an electric field may be generated inside the piezoelectric crystal P5, and the piezoelectric crystal P5 may expand and contract to weaken the vibration toward the nozzle 62. A second operation example described below may solve this problem.

### 2.3.2 Second Operation Example

When the switches S3, S4, S5 are turned on and the switches S1, S2 are turned off as shown in FIG. 14, the first output terminal O1 is connected to the electrode E1 and the second output terminal O2 is connected to the electrode E2 to be in the state a. Further, the second output terminal O2 is also connected to the electrodes E3, E7. According to the above, since both ends of the piezoelectric crystal P2 are connected to the potential +V and both ends of the piezoelectric crystal P5 are connected to the potential +V, the expansion and contraction of the piezoelectric crystals P2, P5 can be suppressed.

When the switches S1, S4, S5 are turned on and the switches S2, S3 are turned off as shown in FIG. 15, the first output terminal O1 is connected to the electrode E2 and the second output terminal O2 is connected to the electrode E3 to be in the state b. Further, the second output terminal O2 is also connected to the electrode E7.

According to the above, since both ends of the piezoelectric crystal P5 are connected to the potential +V, the expansion and contraction of the piezoelectric crystal P5 can be suppressed.

Similarly to FIG. 13, FIG. 16 shows the state c in which the first output terminal O1 is connected to the electrode E3 and the second output terminal O2 is connected to the electrode E7.

With the operation described above, when any one of the first, second, and fifth piezoelectric elements is used, the expansion and contraction of other piezoelectric elements can be suppressed, so that the use conditions of the first, second, and fifth piezoelectric elements become the same. Therefore, the possibility that re-searching for the optimum duty becomes unnecessary becomes higher than that in the first operation example. As a result, downtime can be suppressed.

In both of FIGS. 12 and 15, in the state b in which the first output terminal O1 is connected to the electrode E2 and the second output terminal O2 is connected to the electrode E3, the first output terminal O1 is also connected to the electrode E1. According to the above, since both ends of the piezoelectric crystal P1 are connected to the ground potential GND, the expansion and contraction of the piezoelectric crystal P1 can be suppressed. Further, in both of FIGS. 13 and 16, in the state c in which the first output terminal O1 is connected to the electrode E3 and the second output terminal O2 is connected to the electrode E7, the first output terminal O1 is also connected to the electrodes E1, E2. According to the above, both ends of the piezoelectric crystal P1 are connected to the ground potential GND, and both ends of the piezoelectric crystal are connected to the ground potential GND, so that the expansion and contraction of the piezoelectric crystals P1, P2 can be suppressed.

In other respects, the first embodiment is similar to the comparative example.

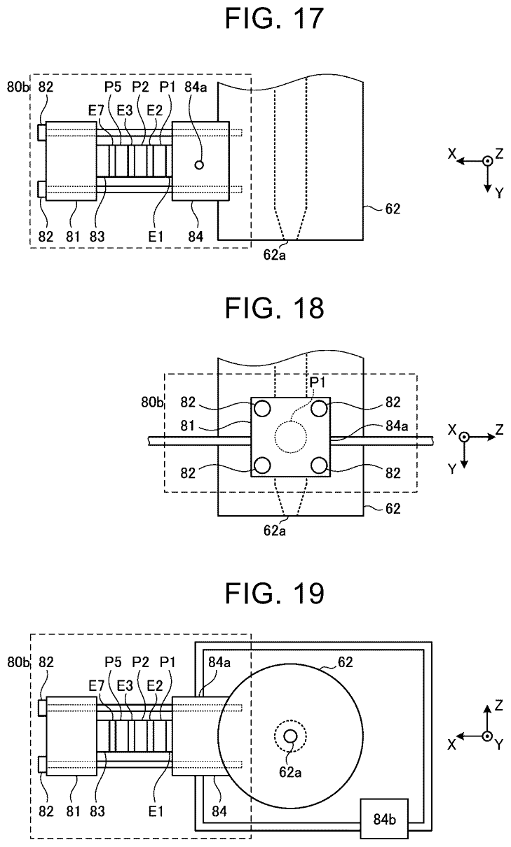

2.4 First Modification FIGS. 17 to 19 show the configuration of a piezoelectric unit 80b in a first modification. In FIG. 17, the piezoelectric element power source 58 and the switching are not shown. The piezoelectric unit 80b circuit 59 differs from the first embodiment in that the cooling member 84 is arranged between the first piezoelectric element and the nozzle 62. The cooling member 84 is similar to that in the comparative example. As a result, heating of the three piezoelectric crystals P1, P2, P5 can be suppressed by the one cooling member 84. The cooling member 84 may also serve as the electrode E1.

In other respects, the first modification is similar to the first embodiment.

### 2.5 Second Modification

### 2.5.1 Configuration

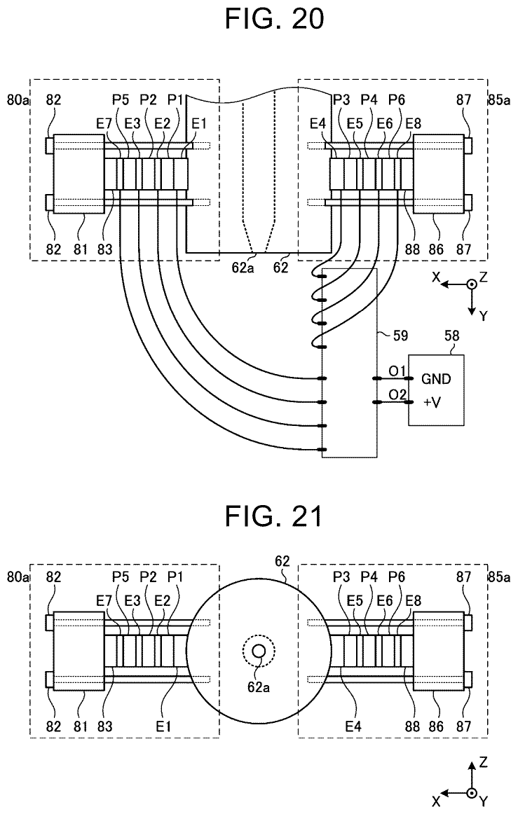

FIGS. 20 and 21 show the configuration of piezoelectric units 80a, 85a in a second modification. FIGS. 20 and 21 show a state of the piezoelectric units 80a, 85a as viewing in the −Z direction and the −Y direction, respectively. The piezoelectric unit 80a is similar to that of the first embodiment. In the piezoelectric unit 85a, third, fourth, and sixth piezoelectric elements, an insulating member 88, and a pressing member 86 are arranged in this order in the −X direction from the side closer to the nozzle 62. The nozzle 62 is located between the first, second, and fifth piezoelectric elements and the third, fourth, and sixth piezoelectric elements.

The third piezoelectric element includes an electrode E4, a piezoelectric crystal P3, and an electrode E5. The fourth piezoelectric element includes the electrode E5, a piezoelectric crystal P4, and an electrode E6. The sixth piezoelectric element includes the electrode E6, a piezoelectric crystal P6, and an electrode E8. In this way, the third piezoelectric element is arranged at a position in the −X direction with respect to the nozzle 62, the fourth piezoelectric element is arranged at a position in the −X direction with respect to the third piezoelectric element, the sixth piezoelectric element is arranged at a position in the −X direction with respect to the fourth piezoelectric element, and the pressing member 86 is arranged at a position in the −X direction with respect to the sixth piezoelectric element. Here, the third and fourth piezoelectric elements share the electrode E5, and the fourth and six piezoelectric elements share the electrode E6. The insulating member 88 is arranged between the pressing member 86 and the electrode E8. Each of plurality of bolts 87 penetrates the pressing member 86 and is fixed to the nozzle 62. The electrodes E4, E5, E6 correspond to the fourth, fifth, and sixth electrodes in the present disclosure, respectively. The −X direction is an example of the second direction in the present disclosure.

The electrodes E4 to E6 and E8 are connected to the switching circuit 59 by electric wires, respectively. The switching circuit 59 switches connection between the first and second output terminals O1, O2 and the electrodes E1 to E8 into any of the above-described states a to c and the following states d to f.
State d: A state in which the first output terminal O1 is connected to the electrode E4 and the second output terminal O2 is connected to the electrode E5
State e: A state in which the first output terminal O1 is connected to the electrode E5 and the second output terminal O2 is connected to the electrode E6
State f: A state in which the first output terminal O1 is connected to the electrode E6 and the second output terminal O2 is connected to the electrode E8

The state d corresponds to the third state in the present disclosure, and the state e corresponds to the fourth state in the present disclosure. The piezoelectric element power source 58 applies a voltage to the third piezoelectric element in the state d, applies a voltage to the fourth piezoelectric element in the state e, and applies a voltage to the sixth piezoelectric element in the state f. Main vibration directions of the third, fourth, and sixth piezoelectric elements are the same, and when a voltage is applied to each of them, the nozzle 62 is vibrated by the expansion and contraction thereof in the X direction.

Here, description has been provided on a case in which three piezoelectric elements are included in the piezoelectric unit 85a. However, two or four or more piezoelectric elements may be included. Further, the piezoelectric crystal P3 may be in direct contact with the nozzle 62 so that the conductive member of the nozzle 62 also serves as the electrode E4. Although description has been provided on the case in which the two piezoelectric units 80a, 85a are arranged on one nozzle 62, three or more piezoelectric units may be arranged as as long an installation space allows. Preferably, the plurality of piezoelectric units are arranged rotationally symmetrically to each other with respect to the center axis of the nozzle 62.

### 2.5.2 First Example of Switching Circuit 59

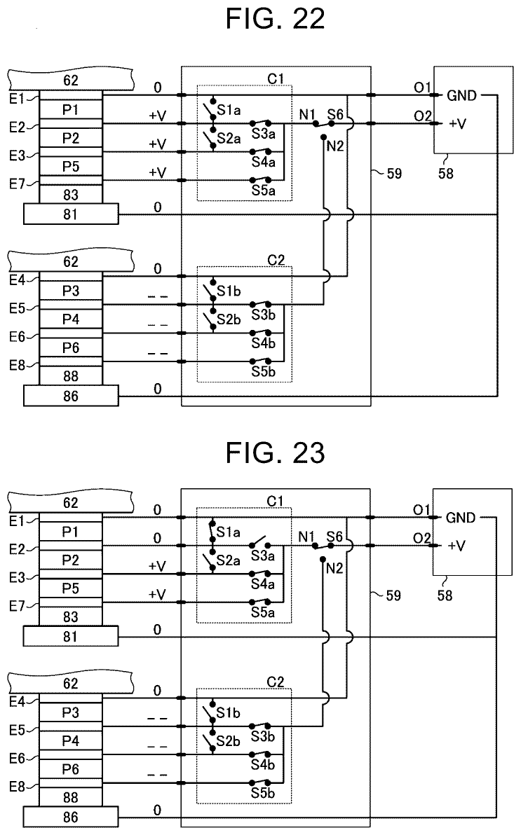

FIGS. 22 to 27 show a first example of the switching circuit 59 in the second modification. FIGS. 22 to 27 all show the same circuit.

The switching circuit 59 includes two input terminals connected to the first and second output terminals O1, O2, respectively, and eight output terminals connected to the electrodes E1 to E8, respectively. The first output terminal O1 is short-circuited to the electrodes E1, E4. The electrode E1 and the electrode E2 are connected via a switch Sla. The electrode E2 and the electrode E3 are connected via a switch S2a. The electrode E4 and the electrode E5 are connected via a switch S1b. The electrode E5 and the electrode E6 are connected via a switch S2b. The second output terminal O2 is connected to a switching switch S6. The switching switch S6 connects the second output terminal O2 selectively to first and second nodes N1, N2. The first node N1 is connected to the electrodes E2, E3, E7 via switches S3a, S4a, S5a, respectively. The second node N2 is connected to the electrodes E5, E6, E8 via switches S3b, S4b, S5b, respectively. The switches Sla to S5a configure a first switching unit C1, and the switches S1b to S5b configure a second switching unit C2.

When the switches S3a, S4a, S5a are turned on and the switches Sla, S2a are turned off in the first switching unit C1 as shown in FIG. 22, the first output terminal O1 is connected to the electrode E1 and the first node N1 is connected to the electrode E2 to be in a first connection state. When the first switching unit C1 is turned into the first connection state with the second output terminal O2 connected to the first node N1 via the switching switch S6 to be in the state a, a voltage is applied to the piezoelectric crystal P1.

When the switches Sla, S4a, S5a are turned on and the switches S2a, S3a are turned off in the first switching unit C1 as shown in FIG. 23, the first output terminal O1 is connected to the electrode E2 and the first node N1 is connected to the electrode E3 to be in a second connection state. When the first switching unit C1 is turned into the second connection state with the second output terminal O2 connected to the first node N1 via the switching switch S6 to be in the state b, a voltage is applied to the piezoelectric crystal P2.

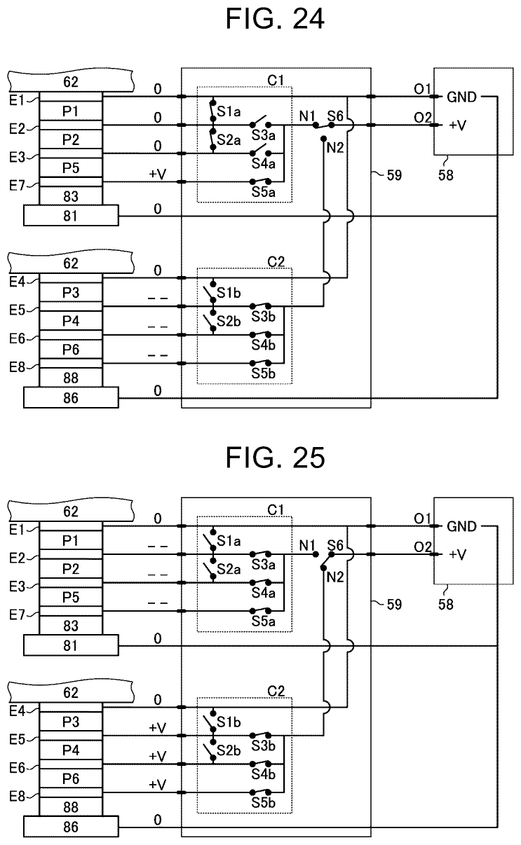

When the switches Sla, S2a, S5a are turned on and the switches S3a, S4a are turned off in the first switching unit C1 as shown in FIG. 24, the first output terminal O1 is connected to the electrode E3 and the first node N1 is connected to the electrode E7. When the second output terminal O2 is connected to the first node N1 via the switching switch S6 to be in the state c, a voltage is applied to the piezoelectric crystal P5.

When the switches S3b, S4b, S5b are turned on and the switches S1b, S2b are turned off in the second switching unit C2 as shown in FIG. 25, the first output terminal O1 is connected to the electrode E4 and the second node N2 is connected to the electrode E5 to be in a third connection state. When the second switching unit C2 is turned into the third connection state with the second output terminal O2 connected to the second node N2 via the switching switch S6 to be in the state d, a voltage is applied to the piezoelectric crystal P3.

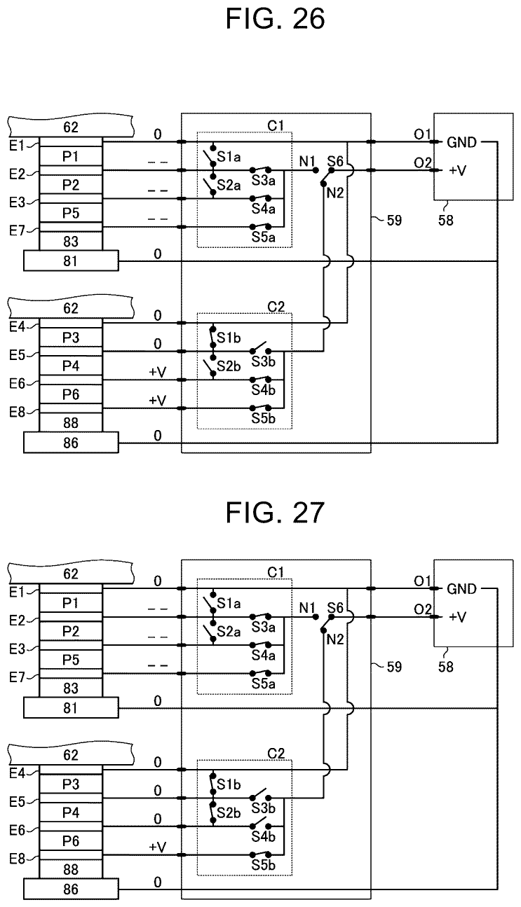

When the switches S1b, S4b, S5b are turned on and the switches S2b, S3b are turned off in the second switching unit C2 as shown in FIG. 26, the first output terminal O1 is connected to the electrode E5 and the second node N2 is connected to the electrode E6 to be in a fourth connection state. When the second switching unit C2 is turned into the fourth connection state with the second output terminal O2 connected to the second node N2 via the switching switch S6 to be in the state e, a voltage is applied to the piezoelectric crystal P4.

When the switches S1b, S2b, S5b are turned on and the switches S3b, S4b are turned off in the second switching unit C2 as shown in FIG. 27, the first output terminal O1 is connected to the electrode E6 and the second node N2 is connected to the electrode E8. When the second output terminal O2 is connected to the second node N2 via the switching switch S6 to be in the state f, a voltage is applied to the piezoelectric crystal P6.

Here, since each of the first and second switching units C1, C2 operates as in the second operation example (see FIGS. 14 to 16), no voltage is applied to the piezoelectric crystals other than one selected piezoelectric crystal. In the present disclosure, not limited to the above, each of the first and second switching units C1, C2 may operate as in the first operation example (see FIGS. 11 to 13).

### 2.5.3 Second Example of Switching Circuit 59

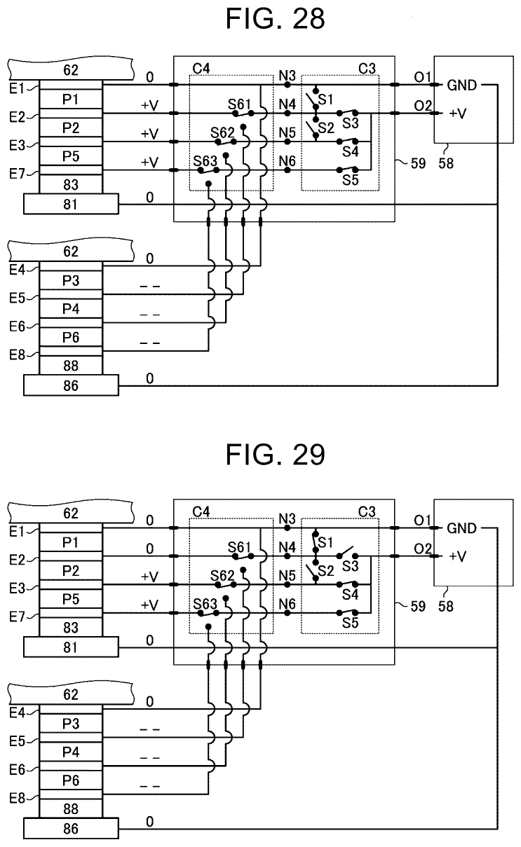

FIGS. 28 to 33 show a second example of the switching circuit 59 in the second modification. FIGS. 28 to 33 all show the same circuit.

The switching circuit 59 includes two input terminals connected to the first and second output terminals O1, O2, respectively, and eight output terminals connected to the electrodes E1 to E8, respectively. The first output terminal O1 is short-circuited to the electrodes E1, E4 via a third node N3. The third node N3 and a fourth node N4 are connected via the switch S1. The fourth node N4 and a fifth node N5 are connected via the switch S2. The second output terminal O2 is connected to the fourth, fifth, and sixth nodes N4, N5, N6 via the switches S3, S4, S5, respectively. The fourth, fifth, and sixth nodes N4, N5, N6 are connected to switching switches S61, S62, S63, respectively. The switching switch S61 connects the fourth node N4 selectively to the electrodes E2, E5. The switching switch S62 connects the fifth node N5 selectively to the electrodes E3, E6. The switching switch S63 connects the sixth node N6 selectively to the electrodes E7, E8. The switches S1 to S5 configure a third switching unit C3, and the switching switches S61 to S63 configure a fourth switching unit C4.

When the switches S3, S4, S5 are turned on and the switches S1, S2 are turned off in the third switching unit C3 as shown in FIGS. 28 and 31, the first output terminal O1 is connected to the third node N3 and the second output terminal O2 is connected to the fourth node N4. This is referred to as a fifth connection state.

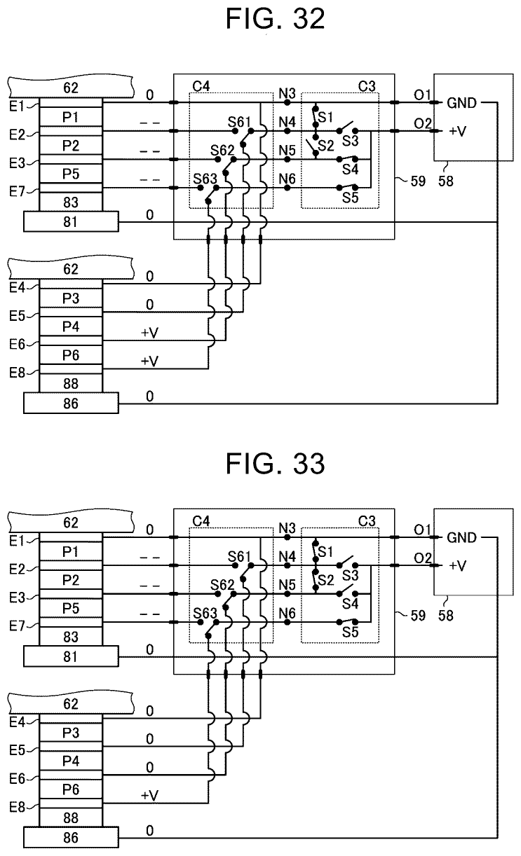

When the switches S1, S4, S5 are turned on and the switches S2, S3 are turned off in the third switching unit C3 as shown in FIGS. 29 and 32, the first output terminal O1 is connected to the fourth node N4 and the second output terminal O2 is connected to the fifth node N5. This is referred to as a sixth connection state.

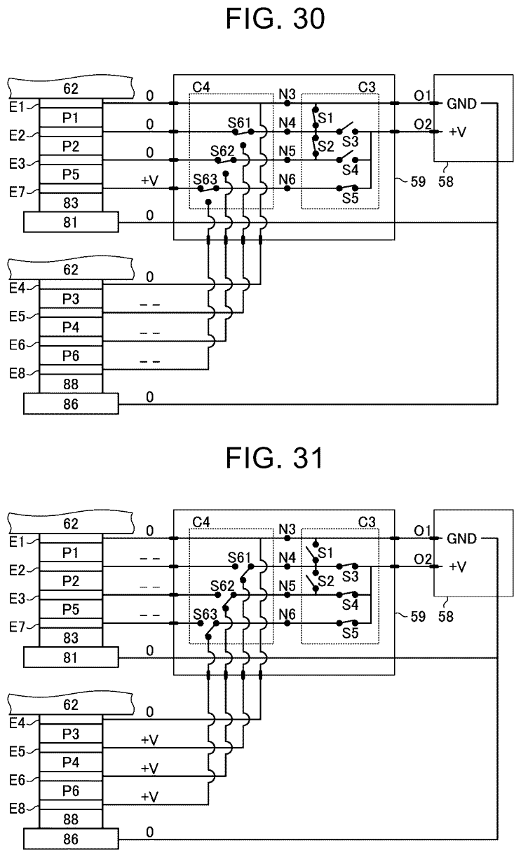

When the switches S1, S2, S5 are turned on and the switches S3, S4 are turned off in the third switching unit C3 as shown in FIGS. 30 and 33, the first output terminal O1 is connected to the fifth node N5 and the second output terminal O2 is connected to the sixth node N6. This is referred to as a ninth connection state.

As shown in FIGS. 28 to 30, in the fourth switching unit C4, the fourth, fifth, and sixth nodes N4, N5, N6 can be connected to the electrodes E2, E3, E7 via the switching switches S61, S62, S63, respectively. This is referred to as a seventh connection state.

As shown in FIGS. 31 to 33, in the fourth switching unit C4, the fourth, fifth, and sixth nodes N4, N5, N6 can be connected to the electrodes E5, E6, E8 via the switching switches S61, S62, S63, respectively. This is referred to as an eighth connection state.

FIG. 28 shows a combination of the fifth connection state and the seventh connection state to be in the state a, and a voltage is applied to the piezoelectric crystal P1.

FIG. 29 shows a combination of the sixth connection state and the seventh connection state to be in the state b, and a voltage is applied to the piezoelectric crystal P2.

FIG. 30 shows a combination of the ninth connection state and the seventh connection state to be in the state c, and a voltage is applied to the piezoelectric crystal P5.

FIG. 31 shows a combination of the fifth connection state and the eighth connection state to be in the state d, and a voltage is applied to the piezoelectric crystal P3.

FIG. 32 shows a combination of the sixth connection state and the eighth connection state to be in the state e, and a voltage is applied to the piezoelectric crystal P4.

FIG. 33 shows a combination of the ninth connection state and the eighth connection state to be in the state f, and a voltage is applied to the piezoelectric crystal P6.

Here, since the third switching unit C3 operates as in the second operation example (see FIGS. 14 to 16), no voltage is applied to the piezoelectric crystals other than one selected piezoelectric crystal. In the present disclosure, not limited to the above, the third switching unit C3 may operate as in the first operation example (see FIGS. 11 to 13).

In other respects, the second modification is similar to the first embodiment.

2.6 Third modification

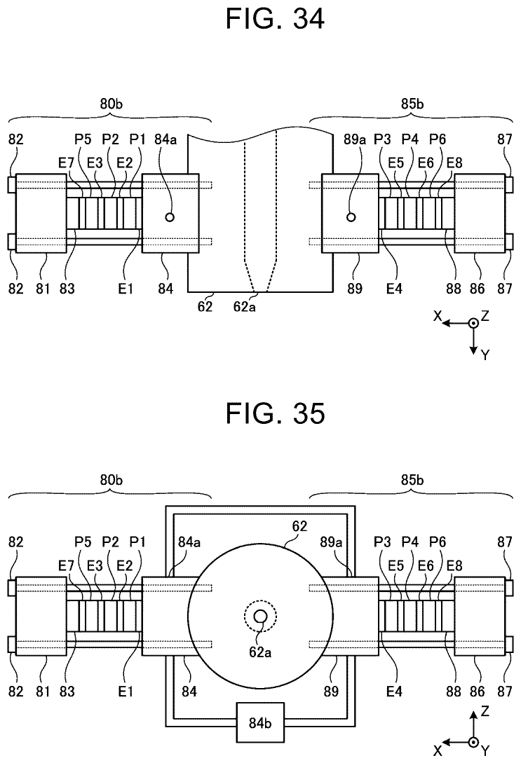

FIGS. 34 and 35 show the configuration of piezoelectric units 80b, 85b in a third modification. The piezoelectric unit 80b is similar to that of the first modification. The piezoelectric unit 85b differs from the second modification in that a cooling member 89 is arranged between the third piezoelectric element and the nozzle 62. The cooling member 89 is similar to the cooling member 84 except for including a flow path 89a for a cooling medium. Although FIG. 35 shows a case in which the flow paths 84a, 89a are connected to the common chiller 84b, they may be connected to separate chillers.

In other respects, the third modification is similar to the second modification.

### 2.7 Fourth Modification

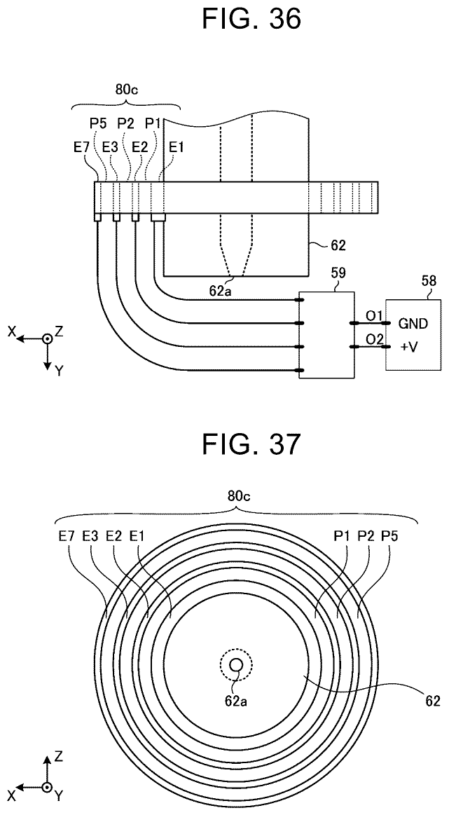

FIGS. 36 and 37 show the configuration of a piezoelectric unit 80c in a fourth modification. The piezoelectric unit 80c includes first, second, and fifth piezoelectric elements which are ring-shaped. The first piezoelectric element includes a ring-shaped electrode E1, a ring-shaped piezoelectric crystal P1, and a ring-shaped electrode E2, and is arranged to surround a capillary-shaped nozzle 62. The second piezoelectric element includes the ring-shaped electrode E2, a ring-shaped piezoelectric crystal P2, and a ring-shaped electrode E3, and is arranged to surround the first piezoelectric element. The fifth piezoelectric element includes the ring-shaped electrode E3, a ring-shaped piezoelectric crystal P5, and a ring-shaped electrode E7, and is arranged to surround the second piezoelectric element. The radial direction directing perpendicularly outward from the center axis of the nozzle 62 is another example of the first direction in the present disclosure.

The first, second, and fifth piezoelectric elements may be fixed to the nozzle 62 by an adhesive, and the pressing member 81, the bolts 82, and the insulating member 83 may not be provided. The nozzle 62 may be formed of an insulator. The ring-shaped first, second, and fifth piezoelectric elements may be longer in the Y direction than shown in FIG. 36.

In other respects, the fourth modification is similar to the first embodiment.

### 2.8 Effect

(1) According to the first embodiment and the first to third modifications, the target generation device 26 includes the nozzle 62, the first piezoelectric element, and the second piezoelectric element. The nozzle 62 includes the nozzle hole 62a that discharges the liquid target substance for generating extreme ultraviolet light. The first piezoelectric element is arranged at a different position in the X direction with respect to the nozzle 62, and vibrates the nozzle 62 by expanding and contracting in the X direction. The second piezoelectric element is arranged at a different position in the X direction with respect to the first piezoelectric element, and vibrates the nozzle 62 via the first piezoelectric element by expanding and contracting in the X direction.

According to the above, the number of mounted piezoelectric elements is increased by arranging a plurality of piezoelectric elements in a stacked manner, so that, when one piezoelectric element deteriorates or fails, another piezoelectric element can be used as a spare piezoelectric element. Therefore, the lifetime of the piezoelectric unit 80a or the target generation device 26 may be extended, and the replacement frequency may be reduced. Further, by stacking a plurality of piezoelectric elements in the X direction, the installation space of the piezoelectric unit 80a for one piezoelectric element can be reduced. Further, it is possible to reduce the time and effort of switching the piezoelectric element such as searching for the optimum duty.

(2) According to the first embodiment and the first to fourth modifications, the first piezoelectric element includes the electrode E1 and the electrode E2, and the second piezoelectric element includes the electrode E2 and the electrode E3.

According to the above, since the first and second piezoelectric elements share the electrode E2, the installation space can be reduced.

(3) According to the first embodiment and the first to third modifications, the target generation device 26 includes the conductive pressing member 81 arranged at a position different in the X direction with respect to the second piezoelectric element, the conductive bolts 82 fixed to the nozzle 62 while penetrating the pressing member 81, and the insulating member 83 arranged between the pressing member 81 and the electrode E3.

According to the above, even if a plurality of piezoelectric elements are mounted on the target generation device 26, the pressing member 81, the bolts 82, and the insulating member 83 can be shared.

(4) According to the first embodiment and the first to fourth modifications, the target generation device 26 includes the piezoelectric element power source 58 and the switching circuit 59. The piezoelectric element power source 58 includes the first and second output terminals O1, O2, and generates a voltage between the first and second output terminals O1, O2. The switching circuit 59 performs switching between the state a in which the first output terminal O1 is connected to the electrode E1 and the second output terminal O2 is connected to the electrode E2, and the state b in which the first output terminal O1 is connected to the electrode E2 and the second output terminal O2 is connected to the electrode E3.

According to the above, the plurality of piezoelectric elements can be individually operated by the operation of the switching circuit 59.

(5) According to the first embodiment and the first to fourth modifications, the target generation device 26 includes the target generation processor 51 that, when switching is performed from the state a to the state b, acquires the detection result of the target substance discharged from the nozzle 62 while changing the duty ratio of the voltage applied to the second piezoelectric element, and searches for the optimum value of the duty ratio.

According to the above, even if the piezoelectric element is switched, appropriate vibration can be transmitted to the nozzle 62 by searching for the optimum duty.

(6) According to the second operation example of the first embodiment, the switching circuit 59 also connects the second output terminal O2 to the electrode E3 in the state a.

According to the above, since the voltage between the electrodes E2, E3 becomes substantially zero, the displacement of the second piezoelectric element can be suppressed. Further, the possibility that the searching for the optimum duty can be omitted is increased.

(7) According to the first and second operation examples of the first embodiment, the switching circuit 59 also connects the first output terminal O1 to the electrode E1 in the state b.

According to the above, since the voltage between the electrodes E1, E2 becomes substantially zero, the displacement of the first piezoelectric element can be suppressed.

(8) According to the first and third modifications, the target generation device 26 includes the cooling member 84, which includes the flow path 84a of a cooling medium, between the first piezoelectric element and the nozzle 62.

According to the above, the cooling mechanism for suppressing temperature of plurality of rise a piezoelectric elements can be shared.

(9) According to the second and third modifications, the target generation device 26 includes the third piezoelectric element and the fourth piezoelectric element. The third piezoelectric element is arranged at a different position in the −X direction, which is a direction different from the X direction, with respect to the nozzle 62, and vibrates the nozzle 62 by expanding and contracting in the −X direction. The fourth piezoelectric element is arranged at a different position in the −X direction with respect to the third piezoelectric element, and vibrates the nozzle 62 via the third piezoelectric element by expanding and contracting in the −X direction. The X and the −X direction intersect the discharge direction direction of the target substance.

According to the above, since the plurality of piezoelectric elements are arranged in each of two directions with respect to the nozzle 62, the number of mounted piezoelectric elements can be increased.

(10) According to the second and third modifications, the nozzle 62 is located between the first piezoelectric element and third piezoelectric element.

According to the above, since the first and third piezoelectric elements are arranged on both sides of the nozzle 62, respectively, the plurality of piezoelectric elements can be arranged in each of the two directions even if the nozzle 62 is small.

(11) According to the second and third modifications, the first piezoelectric element includes the electrode E1 and the electrode E2, the second piezoelectric element includes the electrode E2 and the electrode E3, the third piezoelectric element includes the electrode E4 and the electrode E5, and the fourth piezoelectric element includes the electrode E5 and the electrode E6.

According to the above, since the first and second piezoelectric elements share the electrode E2 and the third and fourth piezoelectric elements share the electrode E5, the installation space can be reduced.

(12) According to the second and third modifications, the target generation device 26 includes the piezoelectric element power source 58 and the switching circuit 59. The piezoelectric element power source 58 includes the first and second output terminals O1, O2, and generates a voltage between the first and second output terminals O1, O2. The switching circuit 59 performs switching among the state a in which the first output terminal O1 is connected to the electrode E1 and the second output terminal O2 is connected to the electrode E2, the state b in which the first output terminal O1 is connected to the electrode E2 and the second output terminal O2 is connected to the electrode E3, the state d in which the first output terminal O1 is connected to the electrode E4 and the second output terminal O2 is connected to the electrode E5, and the state e in which the first output terminal O1 is connected to the electrode E5 and the second output terminal O2 is connected to the electrode E6.

According to the above, the first to fourth piezoelectric elements can be individually operated by the operation of the switching circuit 59.

(13) According to the first example of the switching circuit 59 of the second modification, the target generation device 26 includes the piezoelectric element power source 58 and the switching circuit 59. The piezoelectric element power source 58 includes the first and second output terminals O1, O2, and generates a voltage between the first and second output terminals O1, O2. The switching circuit 59 includes the switching switch S6, the first switching unit C1, and the second switching unit C2. The switching switch S6 connects the second output terminal O2 to either one of the first and second nodes N1, N2. The first switching unit C1 performs switching, with the second output terminal O2 connected to the first node N1, between the first connection state in which the first output terminal O1 is connected to the electrode E1 and the first node N1 is connected to the electrode E2, and the second connection state in which the first output terminal O1 is connected to the second electrode E2 and the first node N1 is connected to the electrode E3. The second switching unit C2 performs switching, with the second output terminal O2 connected to the second node N2, between the third connection state in which the first output terminal O1 is connected to the electrode E4 and the second node N2 is connected to the electrode E5, and the fourth connection state in which the first output terminal O1 is connected to the electrode E5 and the second node N2 is connected to the electrode E6.

According to the above, the first and second switching units C1, C2 can have the same configuration, so that the cost of designing and manufacturing thereof can be reduced.

(14) According to the second example of the switching circuit 59 of the second modification, the target generation device 26 includes the piezoelectric element power source 58 and the switching circuit 59. The piezoelectric element power source 58 includes the first and second output terminals O1, O2, and generates a voltage between the first and second output terminals O1, O2. The switching circuit 59 includes the third switching unit C3 and the fourth switching unit C4. The third switching unit C3 performs switching between the fifth connection state in which the first output terminal O1 is connected to the electrodes E1, E4 via the third node N3 and the second output terminal O2 is connected to the fourth node N4, and the sixth connection state in which the first output terminal O1 is connected to the fourth node N4 and the second output terminal O2 is connected to the fifth node N5. The fourth switching unit C4 performs switching between the seventh connection state in which the fourth node N4 is connected to the electrode E2 and the fifth node N5 is connected to the electrode E3, and the eighth connection state in which the fourth node N4 is connected to the electrode E5 and the fifth node N5 is connected to the electrode E6.

According to the above, since the third switching unit C3 is shared in the connections from the piezoelectric element power source 58 to the electrodes E1 to E3 and E7 and to the electrodes E4 to E6 and E8, the number of switches can be reduced as compared with the first example, and the risk of failure can be reduced.

(15) According to the fourth modification, the first piezoelectric element is arranged to surround the nozzle 62 and the second piezoelectric element is arranged to surround the first piezoelectric element.

According to the above, the plurality of piezoelectric elements can be securely fixed even if the nozzle 62 is thin.

### 3. PIEZOELECTRIC UNIT 80A ATTACHED TO BOTTOM SURFACE OF NOZZLE 62

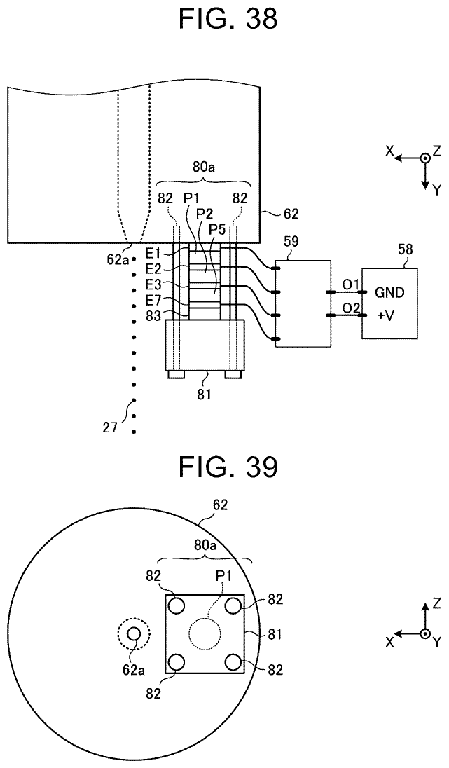

FIGS. 38 and 39 show the configuration of the piezoelectric unit 80a in a second embodiment. In the piezoelectric unit 80a attached to the bottom surface of the nozzle 62, first, second, and fifth piezoelectric elements, the insulating member 83, and the pressing member 81 are arranged in this order in the Y direction from the side closer to the nozzle 62. The Y direction is another example of the first direction in the present disclosure.

In other respects, the second embodiment is similar to the first embodiment.

### 3.1 Fifth Modification

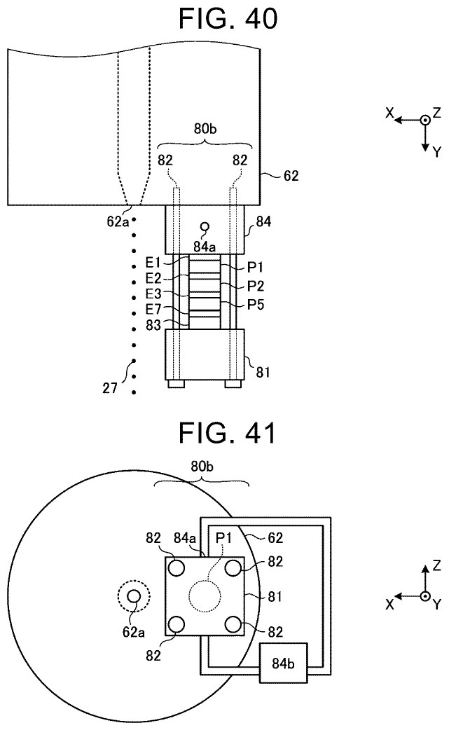

FIGS. 40 and 41 show the configuration of a piezoelectric unit 80b in a fifth modification. In the piezoelectric unit 80b attached to the bottom surface of the nozzle 62, the cooling member 84, the first, second, and fifth piezoelectric elements, the insulating member 83, and the pressing member 81 are arranged in this order in the Y direction from the side closer to the nozzle 62.

In other respects, the fifth modification is similar to the first modification.

### 3.2 Sixth Modification

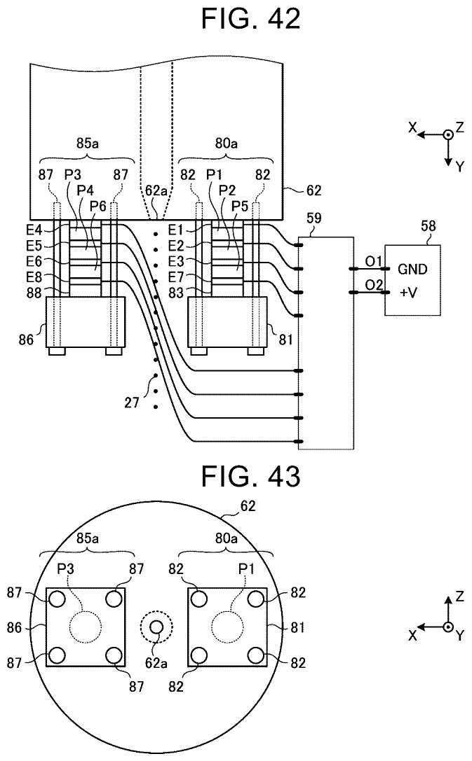

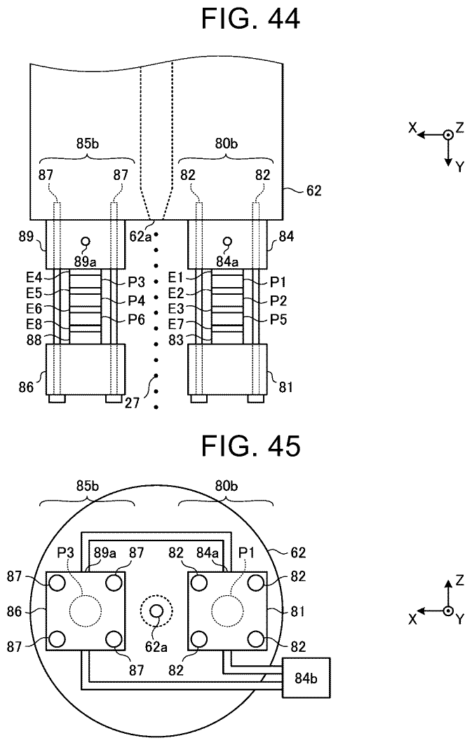

FIGS. 42 and 43 show the configuration of the piezoelectric units 80a, 85a in a sixth modification. In the piezoelectric unit 80a attached to the bottom surface of the nozzle 62, the second, first, and fifth piezoelectric elements, the insulating member 83, and the pressing member 81 are arranged in this order in the Y direction from the side closer to the nozzle 62. In the piezoelectric unit 85a attached to the bottom surface of the nozzle 62, the third, fourth, and sixth piezoelectric elements, the insulating member 88, and the pressing member 86 are arranged in this order in the Y direction from the side closer to the nozzle 62. The trajectory of the target 27 discharged from the nozzle 62 is located between the piezoelectric units 80a, 85a.

In other respects, the sixth modification is similar to the second modification.

### 3.3 Seventh Modification

FIGS. 4 and 45 show the configuration of the piezoelectric units 80b, 85b in a seventh modification. In the piezoelectric unit 80b attached to the bottom surface of the nozzle 62, the cooling member 84, the first, second, and fifth piezoelectric elements, the insulating member 83, and the pressing member 81 are arranged in this order in the Y direction from the side closer to the nozzle 62. In the piezoelectric unit 85b attached to the bottom surface of the nozzle 62, the cooling member 89, the third, fourth, and sixth piezoelectric elements, the insulating member 88, and the pressing member 86 are arranged in this order in the Y direction from the side closer to the nozzle 62. The trajectory of the target 27 discharged from the nozzle 62 is located between the piezoelectric units 80b, 85b.

In other respects, the seventh modification is similar to the third modification.

### 3.4 Effect

(16) According to the second embodiment and the fifth to seventh modifications, the target generation device 26 includes the first piezoelectric element and the second piezoelectric element. The first piezoelectric element is arranged at a different position in the Y direction with respect to the nozzle 62, and vibrates the nozzle 62 by expanding and contracting in the Y direction. The second piezoelectric element is arranged at a different position in the Y direction with respect to the first piezoelectric element, and vibrates the nozzle 62 via the first piezoelectric element by expanding and contracting in the Y direction. The Y direction is parallel to the discharge direction of the target substance.

According to the above, by arranging piezoelectric elements on the bottom surface of the nozzle 62, it is possible to reduce the installation space of the plurality of piezoelectric elements in the X direction.

(17) According to the sixth and seventh modifications, the target generation device 26 includes the third piezoelectric element and the fourth piezoelectric element. The third piezoelectric element is arranged at a different position in the Y direction with respect to the nozzle 62, and vibrates the nozzle 62 by expanding and contracting in the Y direction. The fourth piezoelectric element is arranged at a different position in the Y direction with respect to the third piezoelectric element, and vibrates the nozzle 62 via the third piezoelectric element by expanding and contracting in the Y direction. The trajectory of the target substance discharged from the nozzle 62 is located between the first piezoelectric element and the third piezoelectric element.

According to the above, since the first and second piezoelectric elements and the third and fourth piezoelectric elements are arranged on both sides of the trajectory of the target substance, respectively, a number of piezoelectric elements can be arranged even if the nozzle 62 is small.

### 4. OTHERS

### 4.1 Examples of EUV Light Utilization Apparatus 6

FIG. 46 shows the configuration of the exposure apparatus 6a connected to the EUV light generation system 11. The exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11. The workpiece irradiation unit 609 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 47 shows the configuration of the inspection apparatus 6b connected to the EUV light generation system 11. The inspection apparatus as the EUV light utilization apparatus 6 (see FIG. 1) includes an illumination optical system 603 and a detection optical system 606. The illumination optical system 603 reflects the EUV light incident from the EUV light generation system 11 to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. Inspection for a defect of the mask 605 is performed based on the image of the mask 605 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 4.2 Processor

The processor such as the EUV light generation processor 5 and the target generation processor 51 may be configured as hardware to execute various physically processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 4.3 Supplement

The description above is intended to be illustrative and the present disclosure is not limited d thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A target generation device comprising:
a nozzle including a nozzle hole through which a liquid target substance for generating extreme ultraviolet light is discharged;
a first piezoelectric element arranged at a different position in a first direction with respect to the nozzle, and configured to vibrate the nozzle by expanding and contracting in the first direction; and
a second piezoelectric element arranged at a different position in the first direction with respect to the first piezoelectric element, and configured to vibrate the nozzle via the first piezoelectric element by expanding and contracting in the first direction.

2. The target generation device according to claim 1,
wherein the first piezoelectric element includes a first electrode and a second electrode, and the second piezoelectric element includes the second electrode and a third electrode.

3. The target generation device according to claim 2, further comprising:
a conductive pressing member arranged at a different position in the first direction with respect to the second piezoelectric element;
a conductive bolt fixed to the nozzle as penetrating the pressing member; and
an insulating member arranged between the pressing member and the third electrode.

4. The target generation device according to claim 2, further comprising:
a piezoelectric element power source including first and second output terminals, and configured to generate a voltage between the first and second output terminals; and
a switching circuit configured to perform switching between a first state in which the first output terminal is connected to the first electrode and the second output terminal is connected to the second electrode, and a second state in which the first output terminal is connected to the second electrode and the second output terminal is connected to the third electrode.

5. The target generation device according to claim 4,
further comprising a processor configured, when the switching is performed from the first state to the second state, to acquire a detection result of the target substance discharged from the nozzle while changing a duty ratio of a voltage applied to the second piezoelectric element, and to search for an appropriate value of the duty ratio.

6. The target generation device according to claim 4,
wherein the switching circuit connects the second output terminal also to the third electrode in the first state.

7. The target generation device according to claim 4,
wherein the switching circuit connects the first output terminal also to the first electrode in the second state.

8. The target generation device according to claim 1,
further comprising a cooling member including a flow path of a cooling medium between the first piezoelectric element and the nozzle.

9. The target generation device according to claim 1, further comprising:
a third piezoelectric element arranged at a different position in a second direction different from the first direction with respect to the nozzle, and configured to vibrate the nozzle by expanding and contracting in the second direction; and
a fourth piezoelectric element arranged at a different position in the second direction with respect to the third piezoelectric element, and configured to vibrate the nozzle via the third piezoelectric element by expanding and contracting in the second direction,
wherein the first and second directions intersect a discharge direction of the target substance.

10. The target generation device according to claim 9,
wherein the nozzle is located between the first piezoelectric element and the third piezoelectric element.

11. The target generation device according to claim 9,
wherein the first piezoelectric element includes a first electrode and a second electrode,
the second piezoelectric element includes the second electrode and a third electrode,
the third piezoelectric element includes a fourth electrode and a fifth electrode, and
the fourth piezoelectric element includes the fifth electrode and a sixth electrode.

12. The target generation device according to claim 11, further comprising:
a piezoelectric element power source including first and second output terminals, and configured to generate a voltage between the first and second output terminals; and
a switching circuit configured to perform switching among a first state in which the first output terminal is connected to the first electrode and the second output terminal is connected to the second electrode, a second state in which the first output terminal is connected to the second electrode and the second output terminal is connected to the third electrode, a third state in which the first output terminal is connected to the fourth electrode and the second output terminal is connected to the fifth electrode, and a fourth state in which the first output terminal is connected to the fifth electrode and the second output terminal is connected to the sixth electrode.

13. The target generation device according to claim 11, further comprising:
a piezoelectric element power source including first and second output terminals, and configured to generate a voltage between the first and second output terminals; and
a switching circuit,
wherein the switching circuit includes:
a switching switch configured to connect the second output terminal to either one of first and second nodes;
a first switching unit configured to perform switching, with the second output terminal connected to the first node, between a first connection state in which the first output terminal is connected to the first electrode and the first node is connected to the second electrode, and a second connection state in which the first output terminal is connected to the second electrode and the first node is connected to the third electrode; and
a second switching unit configured to perform switching, with the second output terminal connected to the second node, between a third connection state in which the first output terminal is connected to the fourth electrode and the second node is connected to the fifth electrode, and a fourth connection state in which the first output terminal is connected to the fifth electrode and the second node is connected to the sixth electrode.

14. The target generation device according to claim 11, further comprising:
a piezoelectric element power source including first and second output terminals, and configured to generate a voltage between the first and second output terminals; and
a switching circuit,
wherein the switching circuit includes:
a third switching unit configured to perform switching between a fifth connection state in which the first output terminal is connected to the first and fourth electrodes via a third node and the second output terminal is connected to a fourth node, and a sixth connection state in which the first output terminal is connected to the fourth node and the second output terminal is connected to a fifth node; and
a fourth switching unit configured to perform switching between a seventh connection state in which the fourth node is connected to the second electrode and the fifth node is connected to the third electrode, and an eighth connection state in which the fourth node is connected to the fifth electrode and the fifth node is connected to the sixth electrode.

15. The target generation device according to claim 1,
wherein the first piezoelectric element is arranged as surrounding the nozzle, and the second piezoelectric element is arranged as surrounding the first piezoelectric element.

16. The target generation device according to claim 1,
wherein the first direction is parallel toa discharge direction of the target substance.

17. The target generation device according to claim 16, further comprising:
a third piezoelectric element arranged at a different position in the first direction with respect to the nozzle, and configured to vibrate the nozzle by expanding and contracting in the first direction; and
a fourth piezoelectric element arranged at a different position in the first direction with respect to the third piezoelectric element, and configured to vibrate the nozzle via the third piezoelectric element by expanding and contracting in the first direction,
wherein a trajectory of the target substance discharged from the nozzle is located between the first piezoelectric element and the third piezoelectric element.

18. An extreme ultraviolet light generation system, comprising:
the target generation device according to claim 1;
a laser device configured to irradiate the target substance discharged from the nozzle with laser light; and
an EUV light concentrating mirror configured to concentrate the extreme ultraviolet light generated by irradiating the target substance with the laser light.

19. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system including:
a target generation device including:
a nozzle including a nozzle hole through which a liquid target substance for generating the extreme ultraviolet light is discharged,
a first piezoelectric element arranged at a different position in a first direction with respect to the nozzle, and configured to vibrate the nozzle by expanding and contracting in the first direction, and
a second piezoelectric element arranged at a different position in the first direction with respect to the first piezoelectric element, and configured to vibrate the nozzle via the first piezoelectric element by expanding and contracting in the first direction;
a laser device configured to irradiate the target substance discharged from the nozzle with laser light; and
an EUV light concentrating mirror configured to concentrate the extreme ultraviolet light generated by irradiating the target substance with the laser light.

20. An electronic device manufacturing method, comprising:
inspecting a defect of a mask by irradiating the mask with extreme ultraviolet light generated by an extreme ultraviolet light generation system;
selecting a mask using a result of the inspection; and
exposing and transferring a pattern formed on the selected mask onto a photosensitive substrate,
extreme ultraviolet light generation system the including:
a target generation device including:
a nozzle including a nozzle hole through which a liquid target substance for generating the extreme ultraviolet light is discharged,
a first piezoelectric element arranged at a different position in a first direction with respect to the nozzle, and configured to vibrate the nozzle by expanding and contracting in the first direction, and
a second piezoelectric element arranged at a different position in the first direction with respect to the first piezoelectric element, and configured to vibrate the nozzle via the first piezoelectric element by expanding and contracting in the first direction;
a laser device configured to irradiate the target substance discharged from the nozzle with laser light; and
an EUV light concentrating mirror configured to concentrate the extreme ultraviolet light generated by irradiating the target substance with the laser light.
